(19) United States
(12) Patent Application Publication
(10) Pub. No.: US 2026/0260681 A1
(43) Pub. Date: Sep. 3, 2026

(54) FERROELECTRIC MEMORY DEVICES AND OPERATION METHODS THEREOF

(71) Applicant: Yangtze Memory Technologies Co., Ltd., Wuhan (CN)

(72) Inventors: Junyi LIAO, Wuhan (CN); Feng XU, Wuhan (CN); Xiangnan ZHAO, Wuhan (CN); Da LI, Wuhan (CN); Lei JIN, Wuhan (CN)

(21) Appl. No.: 19/176,278

(22) Filed: Apr. 11, 2025

(30) Foreign Application Priority Data
Mar. 3, 2025 (CN) 202510244986.5

(51) Int. Cl. G11C 11/22

(52) U.S. Cl. CPC G11C 11/2275; G11C 11/2259; G11C 11/2273; G11C 11/2293

(57) ABSTRACT

Systems, devices, and methods for operating a ferroelectric device are provided. In one aspect, a method of operating a ferroelectric memory device includes: performing, during a first phase, a program operation on a first ferroelectric memory cell, including: applying a program voltage to a first word line coupled to the first ferroelectric memory cell, and applying a pass voltage to a second word line coupled to a second ferroelectric memory cell; and performing, during a second phase after the first phase, a second operation, including: applying a first voltage to the second word line; applying a second voltage to a source line; and applying a third voltage to a bit line. At least one of the second voltage or the third voltage is greater than the first voltage.

### CROSS-REFERENCE TO RELATED APPLICATIONS

This application claims priority to Chinese Patent Application No. 202510244986.5, filed on Mar. 3, 2025, which is hereby incorporated by reference in its entirety.

### TECHNICAL FIELD

The present disclosure relates to ferroelectric memory devices and operation methods for ferroelectric memory devices.

### BACKGROUND

Semiconductor devices may be classified into non-volatile memory devices, such as flash memory devices, NAND memory device, or ferroelectric memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for ferroelectric memory devices and operation methods thereof.

One aspect of the present disclosure features a method of operating a ferroelectric memory device, including: performing, during a first phase, a program operation on a first ferroelectric memory cell, including: applying a program voltage to a first word line coupled to the first ferroelectric memory cell, and applying a pass voltage to a second word line coupled to a second ferroelectric memory cell; and performing, during a second phase after the first phase, a second operation, including: applying a first voltage to the second word line; applying a second voltage to a source line; and applying a third voltage to a bit line, where at least one of the second voltage or the third voltage is greater than the first voltage.

In some implementations, the first voltage is smaller than zero, and the second voltage and the third voltage are about zero.

In some implementations, the first voltage is about zero, the second voltage is greater than zero, and the third voltage is about zero, and where performing, during the second phase after the first phase, the second operation further includes: applying a fourth voltage to a bottom select gate (BSG); and after a first predetermined period, floating the BSG.

In some implementations, the first predetermined period is shorter than a ramping time for the second voltage.

In some implementations, the first voltage and the second voltage are about zero, and the third voltage is greater than zero, and where performing, during the second phase after the first phase, the second operation further includes: applying a fifth voltage to a top select gate (TSG); and after a second predetermined period, floating the TSG.

In some implementations, the second predetermined period is shorter than a ramping time for the third voltage.

In some implementations, the bit line is a first bit line coupled to the first ferroelectric memory cell, and where performing, during the first phase, the program operation on the first ferroelectric memory cell further includes: applying a first bit line voltage to the first bit line; applying a second bit line voltage greater than the first bit line voltage to a second bit line; and applying a source line voltage to the source line.

In some implementations, the first voltage is negative, and an absolute value of the first voltage is smaller than an absolute value of the program voltage.

In some implementations, the second voltage is positive, and the second voltage is smaller than a first erase voltage that is applied to the source line during an erase phase.

In some implementations, the third voltage is positive, and the third voltage is smaller than a second erase voltage that is applied to the bit line during an erase phase.

In some implementations, performing, during the first phase, the program operation on the first ferroelectric memory cell further includes: applying, during the first phase, a BSG voltage to a BSG; applying, during the first phase, a first TSG voltage to a selected TSG; and applying, during the first phase, a second TSG voltage smaller than the first TSG voltage to an unselected TSG.

In some implementations, the method includes performing an increment step pulse programming (ISPP) operation to cause the first ferroelectric memory cell to be a programmed state. Performing the ISPP operation includes applying a plurality of program voltages during a plurality of periods. A last period of the plurality of periods includes the first phase, and a last one of the plurality of program voltages includes the program voltage. Performing the second operation includes performing the second operation during the second phase after the last period of the plurality of periods.

In some implementations, the method includes performing an increment step pulse programming (ISPP) operation to cause the first ferroelectric memory cell to a programmed state. Performing the ISPP operation includes applying a plurality of program voltages during a plurality of periods. Each of the plurality of periods includes the first phase, the plurality of program voltages includes the program voltage, and the plurality of program voltages is different from one another. Performing the second operation includes performing the second operation during the second phase after each period of the plurality of periods.

Another aspect of the present disclosure features a method of operating a ferroelectric memory device, including: performing, during a first phase, a read operation on a first ferroelectric memory cell, including: applying a read voltage to a first word line coupled to the first ferroelectric memory cell, and applying a pass voltage to a second word line coupled to a second ferroelectric memory cell; and performing, during a second phase after the first phase, a second operation, including: applying a first voltage to the second word line; applying a second voltage to a source line; and applying a third voltage to a bit line, where at least one of the second voltage or the third voltage is greater than the first voltage.

In some implementations, the first voltage is smaller than zero, and the second voltage and the third voltage are about zero.

In some implementations, the first voltage is about zero, the second voltage is greater than zero, and the third voltage is about zero, and where performing, during the second phase after the first phase, the second operation further includes: applying a fourth voltage to a bottom select gate (BSG); and after a first predetermined period, floating the BSG.

In some implementations, the first voltage and the second voltage are about zero, and the third voltage is greater than zero, and where performing, during the second phase after the first phase, the second operation further includes: applying a fifth voltage to a top select gate (TSG); and after a second predetermined period, floating the TSG.

In some implementations, performing, during the first phase, the read operation on the first ferroelectric memory cell further includes: applying a source line voltage to the source line; and applying a bit line voltage to the bit line.

In some implementations, the first voltage is negative, and an absolute value of the first voltage is smaller than an absolute value of a program voltage.

In some implementations, the second voltage is positive, and the second voltage is smaller than a first erase voltage that is applied to the source line during an erase phase.

In some implementations, the third voltage is positive, and the third voltage is smaller than a second erase voltage that is applied to the bit line during an erase phase.

In some implementations, performing, during the first phase, the read operation on the first ferroelectric memory cell further includes: applying, during the first phase, a BSG voltage to a BSG; applying, during the first phase, a first TSG voltage to a selected TSG; and applying, during the first phase, a second TSG voltage smaller than the first TSG voltage to an unselected TSG.

In some implementations, the method includes performing, during a plurality of phases, a plurality of read operations on a plurality of ferroelectric memory cells, where the plurality of phases includes the first phase, the plurality of read operations includes the read operation, and the plurality of ferroelectric memory cells includes the first ferroelectric memory cell, and where the second operation is performed after performing the plurality of read operations on the plurality of ferroelectric memory cells.

Another aspect of the present disclosure features a ferroelectric memory device including: a memory array including a first word line and a second word line; and a peripheral circuit coupled to the memory array, where the peripheral circuit is configured to perform operations including: performing, during a first phase, a program operation on a first ferroelectric memory cell, including: applying a program voltage to the first word line coupled to the first ferroelectric memory cell, and applying a pass voltage to the second word line coupled to a second ferroelectric memory cell; and performing, during a second phase after the first phase, a second operation, including: applying a first voltage to the second word line; applying a second voltage to a source line; and applying a third voltage to a bit line, where at least one of the second voltage or the third voltage is greater than the first voltage.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a diagram for a multi-level cell (MLC) in a ferroelectric memory device configured to store two bits of data with different threshold voltage levels.

FIG. 1B illustrates a schematic circuit diagram of an example three-dimensional (3D) ferroelectric memory array.

FIG. 1C illustrates an example 3D semiconductor device with a control structure and a memory structure.

FIG. 1D illustrates an example capacitor structure of the example 3D semiconductor device of FIG. 1C.

FIGS. 2A and 2B illustrate program disturb and read disturb in a ferroelectric memory cell, respectively.

FIG. 2C illustrates trapped charges in a ferroelectric memory cell.

FIG. 2D illustrates an example coupling model between polarization reversal and charge trapping during (1) an initial disturb pulse, (2) an interval, (3) a disturb pulse after the interval, and (4) relaxation before a read operation.

FIG. 3A illustrates a schematic circuit diagram of an example ferroelectric memory array.

FIG. 3B illustrates an example signal diagram of at least part of a program operation and a de-trapping operation.

FIG. 3C illustrates another example signal diagram of at least part of a program operation and a de-trapping operation.

FIG. 3D illustrates yet another example signal diagram of at least part of a program operation and a de-trapping operation.

FIG. 4A illustrates a schematic circuit diagram of the example ferroelectric memory array of FIG. 3A.

FIG. 4B illustrates an example signal diagram of a read operation and a de-trapping operation.

FIG. 4C illustrates another example signal diagram of a read operation and a de-trapping operation.

FIG. 4D illustrates yet another example signal diagram of a read operation and a de-trapping operation.

FIG. 5 is a flow chart of a process of an example method to operate a ferroelectric memory device.

FIG. 6 illustrates a block diagram of an example system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

A memory device, such as a ferroelectric memory device, can apply a program voltage to perform a programming operation to program a memory cell of the ferroelectric memory device. In some aspects, ferroelectric memory cells in a same memory bock of the ferroelectric memory device can share the same word line (WL) and can be programmed simultaneously. During the programming operation, a row decoder can select a WL associated with the memory cell to send a program voltage signal to program the ferroelectric memory cell into a target state. The unselected WLs in the ferroelectric memory block can be biased to a voltage level called “Vpass” to reduce the program disturbance on all unselected cells of the memory block.

An issue with programming a ferroelectric memory cell called “program disturb” can occur when polarization states of some electric dipoles in programmed ferroelectric memory cells become inadvertently reversed during a program operation. For example, during the program operation, the Vpass voltage can be applied to the unselected word lines corresponding to unselected memory cells. At that time, the potential difference between the gate and the channel of the unselected memory cells can form an electric field. The magnitude of the electric field may not be large enough to allow a complete reversal of polarizations of a ferroelectric layer in the ferroelectric memory cells. However, due to the electric field, charges can be trapped at the interface between the ferroelectric layer and a dielectric layer in the ferroelectric memory cell. The trapped charges may induce a polarization reversal on some of the electric dipoles in the ferroelectric layer, thereby causing data corruption. A similar disturb issue can occur during a read operation. Accordingly, the programmed ferroelectric cells may be affected during a program or a read operation. This can reduce the overall reliability of ferroelectric memory device.

Implementations of the present disclosure provide semiconductor devices and methods to form such semiconductor devices. In some implementations, a method of operating a ferroelectric memory device, including: performing, during a first phase, a program operation on a first ferroelectric memory cell, including: applying a program voltage to a first word line coupled to the first ferroelectric memory cell, and applying a pass voltage to a second word line coupled to a second ferroelectric memory cell; and performing, during a second phase after the first phase, a second operation, including: applying a first voltage to the second word line; applying a second voltage to a source line; and applying a third voltage to a bit line, where at least one of the second voltage or the third voltage is greater than the first voltage.

Implementations of the present disclosure can provide one or more of the following technical advantages and/or benefits. For example, during a program operation or a read operation, charges may be trapped at the interface between a ferroelectric layer and a dielectric layer in a ferroelectric memory cell. By applying a de-trapping voltage (e.g., a negative voltage to an unselected word line, or a positive voltage to a source line or a bit line) after a program operation or a read operation, the trapped charges can be reduced. Therefore, the polarization reversal rate in programmed ferroelectric memory cells can be lower. Without limitation to any theories, even if polarizations of some electric dipoles in the ferroelectric memory cells are reversed during a program operation or a read operation, the reversed electric dipoles can be unstable, because insufficient coupled charges and the applied de-trapping field can re-reverse the disturbed electric dipoles. Therefore, the techniques described in the present disclosure can reduce the program disturb and/or read disturb in three-dimensional (3D) ferroelectric memory device (e.g., a FE-NAND device), thereby enhancing its reliability.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

Ferroelectric Random Access Memory (FeRAM) is a high-performance and low-power non-volatile memory that can combine the benefits of conventional non-volatile memories (e.g., Flash and EEPROM) and high-speed RAM (e.g., SRAM and DRAM). FeRAM can outperform existing memories like EEPROM and Flash with less power consumption, faster response, and greater endurance to multiple read-and-write operations. There are two types of FeRAMs: capacitor type, and field-effect transistor (FET) type. A capacitor-type FeRAM cell includes at least one ferroelectric capacitor and at least one MOSFET used for cell selection, also referred to as an nTnC FeRAM memory cell. A FET-type FeRAM cell is capacitor-free and only includes a single ferroelectric-gate FET (FeFET). FET-type FeRAM can be integrated into high-density, because FeFET can be scaled down using the proportionality rule. By replacing the charge trapping storage layer in a 3D NAND flash memory with a ferroelectric material (e.g., Si:HfO₂), a 3D ferroelectric NAND flash memory can be formed.

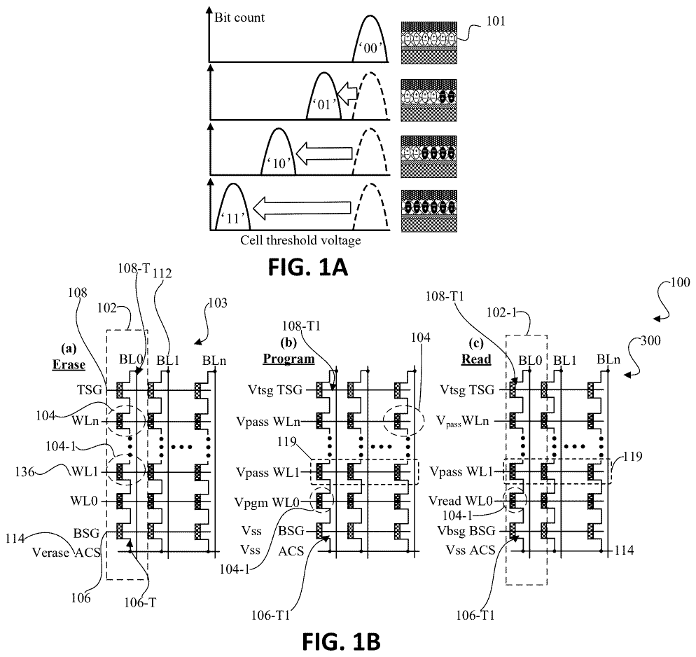

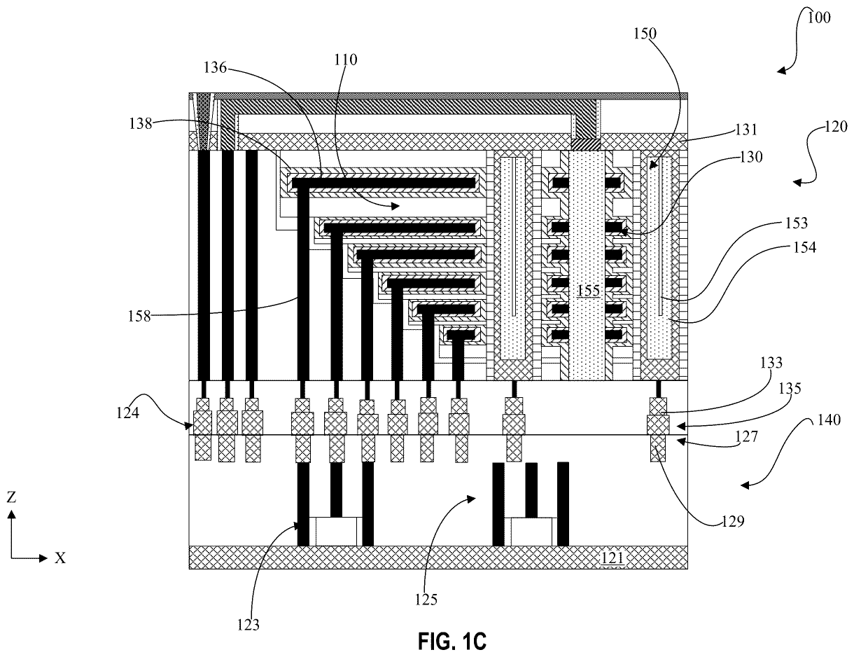

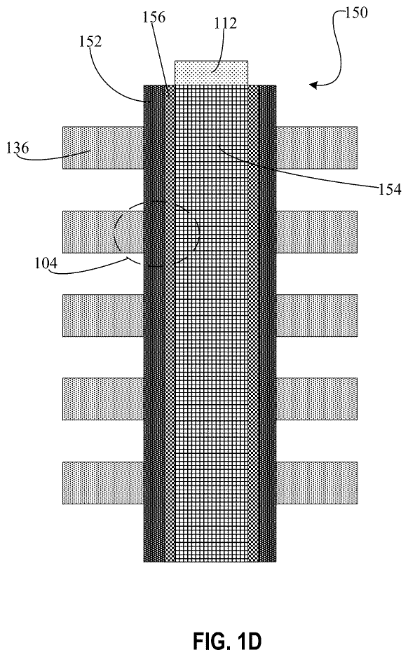

FIG. 1A illustrates a diagram for a multi-level cell (MLC) in a ferroelectric memory device configured to store 2 bits of data with different threshold voltage levels. Without limiting to any particular theory, ferroelectricity is a property observed in non-centrosymmetric dielectric crystals that show a spontaneous electric polarization, where the direction of polarization can be changed by an externally applied electric field. In a ferroelectric material, some atoms in the unit cell may be misplaced to create a permanent electric dipole due to the distribution of electric charge. A macroscopic manifestation of the charge separation is the surface charge of the ferroelectric material, described by a ferroelectric polarization P. Ferroelectric materials, e.g., Lead Zirconate Titanate (PZT), Strontium Bismuth Tantalate (SrBi₂Ta₂O₉ or SBT), Barium Titanate (BaTiO₃), and PbTiO₃, have a perovskite-type crystal structure, where the cation in the center of the unit cell has two positions, both being stable low-energy states. The two low-energy states correspond to two opposite directions of the electric dipole. Under an external electric field, the cation can move in the direction of the electric field. Thus, by applying an external electric field across the crystal, cation in the unit cell can be moved from one low-energy position to another low-energy position, and the direction of the electric dipole can be flipped if the applied electric field is high enough. As a result, the electric polarization P in the ferroelectric material can be aligned with the direction of the external electric field.

A ferroelectric memory cell (e.g., the ferroelectric memory cell 104 of FIG. 1B) can be a single-level cell (SLC) with two possible memory states that can store one bit of data. For example, the first memory state “0” can correspond to a first range of voltages, and the second memory state “1” can correspond to a second range of voltages. In some implementations, each ferroelectric memory cell 104 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state. F

FIG. 1A illustrates an MLC with 2 bits, e.g., including four states, “00,” “01,” “10,” and “11,” representing different configurations of polarization directions. For example, as illustrated in FIG. 1A, the “00” state can correspond to all or substantial all of the electric dipoles in a ferroelectric layer 101 aligning along a first direction and have a first threshold voltage; the “01” state can correspond to a small portion of the electric dipoles aligning along a second direction opposite to the first direction and have a second threshold voltage smaller than the first threshold voltage; the “10” state can correspond to a substantial portion of the electric dipoles aligning along the second direction and have a third threshold voltage smaller than the second threshold voltage; and the “00” state can corresponding to all or substantial all of the electric dipoles aligning along the second direction and have a fourth threshold voltage smaller than the third threshold voltage. It is to be noted that the threshold voltages associated with four different states in a ferroelectric memory cell 104 can be opposite to those of a NAND memory cell (e.g., a device where the cell's threshold voltages depend on an amount of stored charges rather than polarizations of dipoles). For example, in a ferroelectric memory cell 104, the “00” state can correspond to the highest threshold voltage, while “11” state can correspond to the lowest threshold voltage. In contrast, in a NAND memory cell, the “00” state can correspond to the lowest threshold voltage, while the “11” state can correspond to the highest threshold voltage.

FIG. 1B illustrates a schematic circuit diagram of an example ferroelectric memory array 160. The ferroelectric memory array 160 can include a plurality of memory strings 102, each memory string 102 having a plurality of stacked memory cells (e.g., the ferroelectric memory cells 104). In some implementations, each memory string 102 also includes at least one field effect transistor (e.g., MOSFET) at each end, which is controlled by a lower select gate (BSG) 106 and a top select gate (TSG) 108, respectively. And the two respective transistors are referred to as bottom and top select transistors 106-T and 108-T. The vertically stacked ferroelectric memory cells 104 can be controlled by the word lines (WL) 136 (e.g., WL0, . . . , WLn). The drain terminal of the top select transistor 108-T can be connected to the bit line 112, and the source terminal of the lower select transistor 106-T can be connected to a doped source line region, e.g., from where an array common source (ACS) 114 can be formed. In some implementations, multiple array common sources 114 can be electrically connected with each other and shared by the memory strings 102 in an entire memory block. Thus, in some implementations, the array common source 114 is also referred to as the common source line. In this example, the TSG 108 and BSG 106 need to be addressed coordinately to support reading, programing (e.g., writing) and inhibiting operations of a target memory cell (e.g., the ferroelectric memory cell 104-1).

In the ferroelectric memory array 160, read and write operations can be performed in a memory page 119, which includes memory cells sharing the same word line (e.g., WL1 shown in FIG. 1B). In some implementations, the ferroelectric memory cell 104 is a single level cell (SLC), which can be programmed to a logic state of “0” or “1.” In some implementations, the ferroelectric memory cell 104 is a MLC with 2 bites, which can programmed to a logic state of “00”, “01,” “10,” and “11,” as shown in FIG. 1A.

In some implementations, initially, the ferroelectric layer 101 in each ferroelectric memory cell 104 can have zero polarization and can be set or reset to logic state “11” or “00.” At the logic state of “11,” the ferroelectric memory cell 104 can be set to a lower threshold voltage Vth_L, and the current flowing through the ferroelectric memory cells 104 between the source terminal (connected to the array common source 114) and the drain terminal (connected to the bit lines 112) can be at a higher level for a given bias on the word line. At the logic state of “00,” the ferroelectric memory cells 104 can be reset to the higher threshold voltage Vth_H, (e.g., Vth_H>Vth_L) and the current flowing through the ferroelectric memory cells 104 between the source terminal and the drain terminal can be at a lower level for a given bias on the word line. By measuring (e.g., reading) the current that flows through the source and drain terminals of a selected memory cell, the threshold voltage Vth_H or Vth_L and thereby the logic state (or programmed data) of the ferroelectric memory cell 104 can be determined accordingly. In some implementations, the higher and lower threshold voltages Vth_H and Vth_L can be in a range between about −3V to about 3V.

In some examples, as illustrated in diagram (c) of FIG. 1B, to read the data in the target memory cell 104-1 shown in FIG. 1B, which is coupled to the word line WL0 and the bit line BL0, the corresponding TSG 108-T1 and the BSG 106-T1 of a selected memory string 102-1 can be applied with a top select gate voltage Vtsg and a bottom select gate voltage Vbsg to switch on a corresponding top select transistor 108-T1 and a lower select transistor 106-T1. In this example, a current path through the ferroelectric memory cell 104-1 can be established for the selected memory string 102-1. The current flowing through the selected memory string 102-1 can be detected from the bit line 102-1 and the array common source 114 that are electrically coupled to the selected memory string 102-1.

In order to read the storage data in the target memory cell (e.g., the ferroelectric memory cell 104-1), the TSG of unselected memory strings can be applied with an off voltage (Voff) to switch off a corresponding top select transistor. A current path between the unselected memory string 102 and bit line 112 can thereby be disconnected. In this example, storage data can be read from one memory cell 104 at a time.

In some implementations, the TSGs 108 and BSGs 106 of the unselected memory strings 102 can also be applied with the top select gate voltage Vtsg and the bottom select gate voltage Vbsg, respectively, to switch on the corresponding top select transistors 108-T and lower select transistor 106-T, and to establish conductive paths between the bit lines 112 and the unselected memory strings 102. In this example, data stored in the ferroelectric memory cells 104 in the same memory page can be measured simultaneously at respective bit lines 112 by applying the reading voltage Vread at the shared word line WL0. In this example, storage data can be read simultaneously from all the memory cells 104 in one memory page (e.g., a memory page 119).

To read the target memory cell 104-1 in the selected memory string 102-1, a selected word line (e.g., word line WL0) can be applied with the read voltage Vread, while other word lines that are not selected can be applied with a pass voltage Vpass. The pass voltage Vpass can be higher than the highest threshold voltage of all the ferroelectric memory cells 104 such that all the other ferroelectric memory cells 104 on the selected memory string 102-1 can be fully switched on. The read voltage Vread applied on the selected word line WL0 can be adjusted for sensing (e.g., reading or measuring) the threshold voltage of the target memory cell 104-1. In some implementations, the read voltage Vread can have a value in between the lower and higher threshold voltages Vth_L and Vth_H, e.g., Vth_L<Vread<Vth_H. For example, if Vth_L=−2.5V and Vth_H=−1.5V, the read voltage Vread can be in a range between about −2.5V and about −1.5V. As an example, the read voltage Vread can be −2.0 V and the pass voltage Vpass can be 0 V. If the target memory cell 104-1 is at the logic state of “11” having the lower threshold voltage Vth_L, the target memory cell 104-1 can be switched on when applying the read voltage Vread=−2.0 V on the word line WL0. Then, the top and lower select transistors 108-T-2 and 106-T-2, and all the memory cells 104 in the selected memory string 102-1 are switched on. Higher level of current flows between the bit line BL0 and the array common source 114 with a conductive path having a lower resistance. If the target memory cell 104-1 is at the logic state of “00” with the higher threshold voltage Vth_H, the target memory cell 104-1 can be switched off when applying the read voltage Vread=−2.0 V on the word line WL0 as used in the example above. Under this operation condition, even though the top and lower select transistors 108-T1 and 106-T1, and all the other memory cells 104 of the selected memory string 102-1 are switched on, the target memory cell 104-1 is switched off. Lower level of current flows between the bit line BL0 and the array common source 114 with a conductive path having a higher resistance. By measuring the current at bit line BL0, the logic state of the target memory cell 104-1 can be determined.

During the current measurement, a sensing voltage Vsensing can be applied to the bit line BL0, while the array common source 114 can be grounded (e.g., kept at 0V). To avoid disturbing the polarization of the ferroelectric layer 101 in the ferroelectric memory cell 104, the read voltage Vread and the pass voltage Vpass should be less than the coercive voltage V. For example, in some implementations, if the coercive voltage Vc=3.0V, the read voltage Vread and the pass voltage Vpass can range between about −3.0V and about 3.0V. The sensing voltage Vsensing applied to the bit line for sensing (or reading) the current can be low enough without causing significant potential change in a channel layer. The resistance of the target memory cell 104-1 can be extracted from the measured current and the sensing voltage Vsensing. In some implementations, the sensing voltage Vsensing can be in a range between about 0.1V to about 0.5V. As described above, the logic states of “0” and “1” of the target memory cell 104-1, based on threshold voltages of Vth_H and Vth_L, can be determined accordingly.

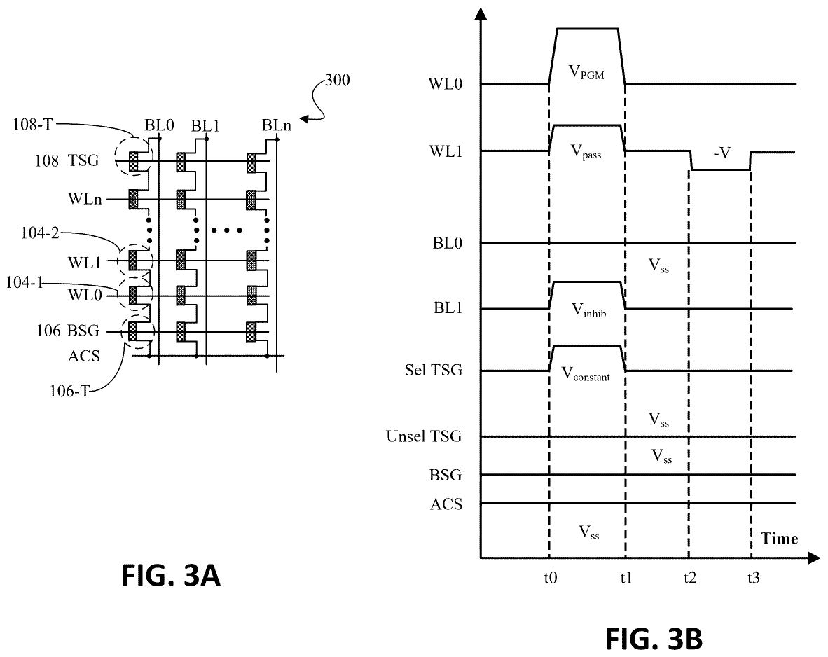

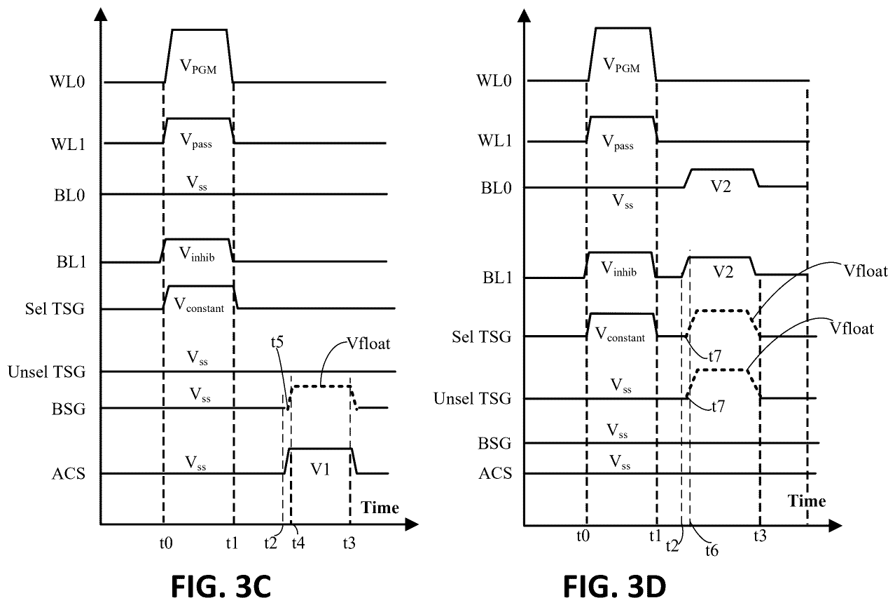

As illustrated in diagram (b) of FIG. 1B, in some implementations, a ferroelectric memory cell 104 can be programmed. For illustration purpose, the target ferroelectric memory cells 104-1 will be used as an example in the subsequent discussions for simplicity. During a program phase, the selected word line WL0 that is coupled to the target ferroelectric memory cells 104-1 can be applied with a program voltage Vpgm, while unselected word lines can be applied with a pass voltage Vpass. The selected bit line can be applied with a first voltage (e.g., Vss), while unselected bit line can be applied with an inhibit voltage Vinhib greater than the first voltage. The corresponding TSG 108-T1 can be applied with top select gate voltage Vtsg (e.g., Vconstant in FIG. 3A) to switch on the TSG 108-T1, while the unselected TSG can be applied with an off voltage. In some implementations, the off voltage is Vss. The corresponding BSG 106-T1 can be applied with an off voltage (e.g., Vss). The ACS can be applied with a ground voltage (e.g., Vss).

As shown in diagram (a) of FIG. 1B, in some implementations, multiple memory cells 104 in a same memory block 103 are erased at the same time. To erase memory cells 104 in the selected memory block 103, the ACS 114 or the bit lines 112 coupled to the selected memory block 103 can be biased with an erase voltage Verase. For example, the erase voltage can be a high positive voltage. In some implementations, an erase operation can be performed at a half-block level, a quarter-block level, or a level having any suitable number of memory blocks or fractions of a memory block.

FIG. 1C illustrates an example 3D ferroelectric memory device 100 with a control structure 140 and a memory structure 120. FIG. 1D illustrates an example capacitor structure of the 3D semiconductor device 100 of FIG. 1C. As used herein, whether one component (e.g., a layer or a device) is “on,” “above,” “over” or “below” another component (e.g., a layer or a device) of a device (e.g., 3D memory device 100) is determined relative to the structure or layer (e.g., second structure 120) in the z-direction (e.g., the vertical direction) when the structure or layer (e.g., second structure 120) is positioned in the lowest tier of the device in the z-direction. The same notion for describing spatial relationships is applied throughout the present disclosure. For ease of description, reference will be made to both FIGS. 1C and 1D when describing the structure of the example 3D ferroelectric memory device 100.

The 3D memory device 100 represents an example of a non-monolithic 3D memory device. The term “non-monolithic” means that the components of 3D memory device 100 (e.g., peripheral circuit and memory array) can be formed separately on different substrates and then joined to form a 3D memory device.

3D memory device 100 can include a control structure (e.g., a first semiconductor structure 140) and a memory structure (e.g., a second semiconductor structure 120). 3D memory device 100 can further include an interconnection structure 124 between first and second semiconductor structures 140 and 120. First and second semiconductor structures 140 and 120 can be fabricated separately (and in parallel in some implementations) such that the thermal budget of fabricating one of first and second semiconductor structures 140 and 120 does not limit the processes of fabricating another one of first and second semiconductor structures 140 and 120. Moreover, a large number of interconnects (e.g., bonding contacts 129, 133 via hybrid bonding) can be formed through the interconnection structure to make direct, short, electrical connections between first semiconductor structure 140 and second semiconductor structure 120, as opposed to the long-distance chip-to-chip data bus on the circuit board, thereby eliminating chip interface delay and achieving high-speed I/O throughput with reduced power consumption. Data transfer between the array of 3D memory strings in second semiconductor structure 120 and the peripheral circuits 125 in control structure 140 can be performed through the interconnects (e.g., bonding contacts via hybrid bonding) across the interconnection structure 124. Furthermore, by vertically integrating first and second semiconductor structures 140 and 120, the chip size can be reduced, and the memory cell density can be increased.

The relative positions of stacked first and second semiconductor structures 140 and 120 and the interconnection structure 124 are not limited. In some implementations, second semiconductor structure 120 can be disposed above first semiconductor structure 140. Nevertheless, in such implementations, interconnection structure 124 can be also formed vertically between first and second semiconductor structures 140 and 120.

In some implementations, the control structure (e.g., a first semiconductor structure 140) includes peripheral circuits 125. The peripheral circuits 125 can be implemented, for example, with advanced logic processes (e.g., technology nodes of 90 nm, 80 nm, 65 nm, 55 nm, 45 nm, 40 nm, 32 nm, 28 nm, 22 nm, 20 nm, 16 nm, 14 nm, 10 nm, 7 nm, 5 nm, 3 nm, etc.) to achieve high speed. In some implementations, the peripheral circuits in the first semiconductor structure 140 are implemented using complementary metal-oxide-semiconductor (CMOS) technology.

In some implementations, the peripheral circuits 125 include any suitable digital, analog, and/or mixed-signal peripheral circuits used for facilitating the operation of 3D memory device 100. For example, the peripheral circuits 125 can include one or more of a page buffer, a decoder (e.g., a row decoder and a column decoder), a sense amplifier, a driver, a charge pump, a current or voltage reference, or any active or passive components of the circuits (e.g., transistors, diodes, resistors, or capacitors). The peripheral circuits 125 can include transistors 123 formed “on” a substrate 121, in which the entirety or part of the transistors 123 are formed in the substrate 121 and/or directly on the substrate 121. Isolation regions (e.g., shallow trench isolations (STIs)) and doped regions (e.g., source regions and drain regions of the transistors) can be formed in the substrate as well. The transistors 123 are high-speed with advanced logic processes, according to some implementations. In some implementations, the peripheral circuit(s) 125 may further include other circuits compatible with the advanced logic processes including logic circuits, such as processors and programmable logic devices (PLDs), or memory circuits, such as SRAM and DRAM.

In some implementations, first semiconductor structure 140 further includes an interconnect layer to transfer electrical signals to and from the peripheral circuits 125. The interconnect layer can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. The interconnect layer can further include one or more interlayer dielectric (ILD) layers (also known as “inter-metal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, tungsten (W), cobalt (Co), copper (Cu), aluminum (Al), silicides, or any combination thereof. The ILD layers in the interconnect layer can include one or more dielectric materials including, but not limited to, silicon oxide, silicon nitride, silicon oxynitride, low dielectric constant (low-k) dielectrics, or any combination thereof.

First semiconductor structure 140 can further include a bonding layer 127. The bonding layer 127 can include bonding contacts 129 and dielectrics electrically isolating the bonding contacts. Bonding contacts 129 can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts 129 and surrounding dielectrics in the bonding layer 127 can be used for hybrid bonding.

In some implementations, the memory structure (e.g., a second semiconductor structure 120) includes an array of 3D memory array. In some implementations, the second semiconductor structure 120 can be a ferroelectric memory device 100, described above in reference to FIGS. 1A and 1B.

Second semiconductor structure 120 can also include a bonding layer 135 that includes a plurality of bonding contacts 133 and dielectrics electrically isolating bonding contacts. The bonding contacts 133 of second semiconductor structure 120 can include conductive materials including, but not limited to, W, Co, Cu, Al, silicides, or any combination thereof. The remaining area of the bonding layer of the second semiconductor structure 120 can be formed with dielectrics including, but not limited to, silicon oxide, silicon nitride, silicon oxynitride, low-k dielectrics, or any combination thereof. The bonding contacts 133 and surrounding dielectrics in the bonding layer 135 of second semiconductor structure 120 can be used for hybrid bonding.

First semiconductor structure 140 can be bonded on top of second semiconductor structure 120 in a face-to-face manner. In some implementations, first and second semiconductor structures 140 and 120 can be bonded by hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously.

In some implementations, second semiconductor structure 120 further includes an interconnect layer to transfer electrical signals. The interconnect layer can include a plurality of interconnects, such as MEOL interconnects and BEOL interconnects. The interconnect layer can further include one or more ILD layers in which the interconnect lines and VIA contacts can form. The interconnect lines and VIA contacts in the interconnect layer can include conductive materials including, but not limited to W, Co, Cu, Al, silicides, or any combination thereof. The ILD layers in the interconnect layer can include one or more materials including, but not limited to, silicon oxide, silicon nitride, silicon oxynitride, low-k dielectrics, or any combination thereof.

In some implementations, 3D memory device 100 is a memory device in which memory cells are provided in the form of an array of memory strings (e.g., the ferroelectric memory string 102 of FIG. 1B). As shown in FIGS. 1C, 3D memory device 100 can include a multi-layer stacked structure 130 disposed over substrate 131. In some implementations, substrate 131 includes silicon (e.g., single crystalline silicon, c-Si), silicon germanium (SiGe), gallium arsenide (GaAs), germanium (Ge), silicon-on-insulator (SOI), or any other suitable materials. The substrate 131 can be a thinned substrate with reduced thickness. Multi-layer stacked structure 130 includes alternately stacked dielectric layers 138 and conductive layers 136. The conductive layers 136 can also be referred to as gate lines 136 or word lines 136 in the present disclosure. The number of the pairs of conductive layers 136 and dielectric layers 138 can determine the number of memory cells in 3D memory device 100. As shown, conductive layers 136 and dielectric layers 138 can alternate in the vertical direction. In other words, except the ones at the top or bottom of multi-layer stacked structure 130, each conductive layer 136 can be sandwiched between two dielectric layers 138, and each dielectric layer 138 can be sandwiched between two conductive layers 136. Conductive layers 136 can include conductive materials, for example, including, but not limited to, W, Co, Cu, Al, polysilicon, doped silicon, silicides, or any combination thereof. Each conductive layer 136 can include, for example, a gate electrode surrounded by an adhesive layer and a gate dielectric layer. The gate electrode of conductive layer 136 can extend laterally as a word line, ending at one or more staircase structures 110 of multi-layer stacked structure 130. Dielectric layers 138 can include one or more dielectric materials, for example, including, but not limited to, silicon oxide, silicon nitride, silicon oxynitride, or any combination thereof.

The multi-layer stacked structure 130 can have a staircase structure 110. The staircase structure 110 of the 3D memory device can be formed along the Z direction (e.g., a vertical direction) and X direction (e.g., word line direction) with progressively truncated lengths of the conductive layers 136 along the word line direction, as illustrated in FIG. 1C. In some implementations, the dielectric layers 138 also have progressively truncated lengths along the word line direction.

3D memory device 100 can further include one or more word line contacts 158 extending in the second semiconductor structure 120 at different depths to connect corresponding conductive layers 136 in the staircase structure 110 of the multi-layer stacked structure 130. The word line contacts 158 can couple out corresponding conductive layers to a control circuit, e.g., a word line driver. In some implementations, the word line contacts include conductive materials, for example, including, but not limited to, W, Co, Cu, Al, polysilicon, doped silicon, silicides, or any combination thereof.

3D memory device 100 further includes capacitor structures 150 extending in the multi-layer stacked structure 130. In some implementations, as illustrated in FIG. 1D, each of the capacitor structures 150 can include a ferroelectric layer 152, a dielectric layer 156, and a channel layer 154. The dielectric layer 156 can be between the ferroelectric layer 152 and the channel layer 154. The ferroelectric layer 152 can be coupled to the conductive layers 136.

In some implementations, the ferroelectric layer 152 includes a ferroelectric material or an anti-ferroelectric material. In some implementations, ferroelectric layer 152 includes one or more dielectric materials, for example, including, but not limited to, Lead Zirconate Titanate (PZT), Strontium Bismuth Tantalate (SBT), Zirconium-doped Hafnium Dioxide (Zr:HfO₂), Aluminum-doped Hafnium Dioxide (Al:HfO₂), Silicon-doped Hafnium Dioxide (Si:HfO₂), Diindium Triselenide (In₂Se₃), Indium Selenide (InSe), or Copper Indium Phosphorus Sulfide (CuInP₂S₆)., or any combination thereof. In some implementations, the channel layer 154 includes amorphous silicon, polycrystalline silicon, monocrystalline silicon, and/or any combination thereof. In some implementations, the dielectric layer 156 includes silicon oxide, silicon nitride, silicon oxynitride, high-k dielectric material (e.g., HfO₂, HfAlO, Al₂O₃), or any combination thereof.

In some implementations, the ferroelectric memory cell 104 (also referred to as the FeFET) can include a FeFET having a structure similar to a metal oxide semiconductor field effect transistor (MOSFET), where the gate (e.g., the conductive layer 136) and the channel (e.g., the channel layer 154) of the transistor can be separated by the ferroelectric layer 152. In some implementations, the dielectric layer 156 is used to reduce the possibility of material intermixing between the ferroelectric layer 152 and the channel layer 154. The effective gate dielectric of a FeFET can be the combination of the ferroelectric layer 152 and the dielectric layer 156. Thinner effective gate dielectric can provide better control of the channel layer 154 from the conductive layer 136. Thus, a thickness of the dielectric layer 156 can be in a range between about 5 nm and about 50 nm.

In some implementations, as illustrated in FIG. 1D, the channel layer 154 fills a center portion of the capacitor structure 150. In some other implementations, as illustrated in FIG. 1C, the capacitor structure 150 further includes a filling layer 153 in the center portion of the capacitor structure 150, and the filling layer 153 is at least partially surrounded by the channel layer 154. Therefore, the channel layer 154 may not fully fill the center portion of the capacitor structure 150. The filling layer 153 can include dielectric materials including, but not limited to, silicon oxide, silicon nitride, silicon oxynitride, or any combination thereof.

In some implementations, the ferroelectric memory cell 104 can further include a barrier layer (not shown in FIG. 1D) between the conductive layer 136 and the ferroelectric layer 152. The barrier layer can be disposed on a sidewall of a capacitor channel hole prior to disposing the ferroelectric layer 152. The barrier layer can be used to block the interactions between the ferroelectric layer 152 and the conductive layer 136. The barrier layer can have a thickness in a range between about 5 nm and about 50 nm. The barrier layer can include silicon oxide, silicon nitride, silicon oxynitride, high-k dielectric materials (e.g., HfO₂, Al₂O₃), and/or any combination thereof.

Referring back to FIGS. 1C, 3D memory device 100 further includes one or more blocking structures 155 extending into multi-layer stacked structure 130. Each of blocking structures 155 can separate one subset of capacitor structures 150 from another subset of capacitor structures 150. In some implementations, blocking structure 155 includes a dielectric material, including, but not limited to, silicon oxide, silicon nitride, silicon oxynitride, or any combination thereof. In some implementations, blocking structure 155 includes a dielectric layer and a conductive layer.

3D memory device 100 further includes bit lines (e.g., as illustrated in FIG. 1D) coupled to one end of the channel layer 154. Bit lines 112 can be formed penetrating a dielectric layer disposed over the multi-layer stacked structure 130, according to some implementations. In some implementations, bit lines 112 can include bit line contacts formed by forming openings in another dielectric layer disposed over the bit line 112, followed by filling the openings with conductive materials such as W, Co, Cu, Al, Ti, TiN, Ta, TaN, doped silicon, silicides, or any combination thereof, and deposited by CVD, PVD, sputtering, evaporating, plating, or any combination thereof. In some implementations, bit lines 112 can be configured to read data stored in the memory cells of 3D memory device 100.

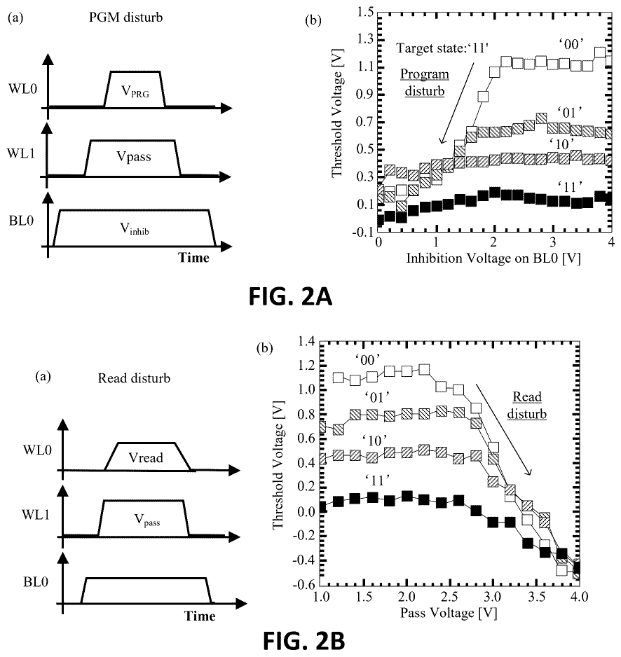

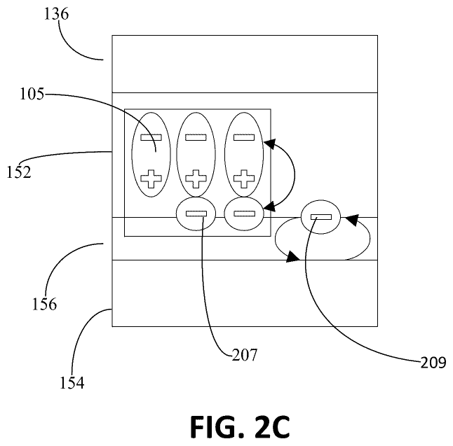

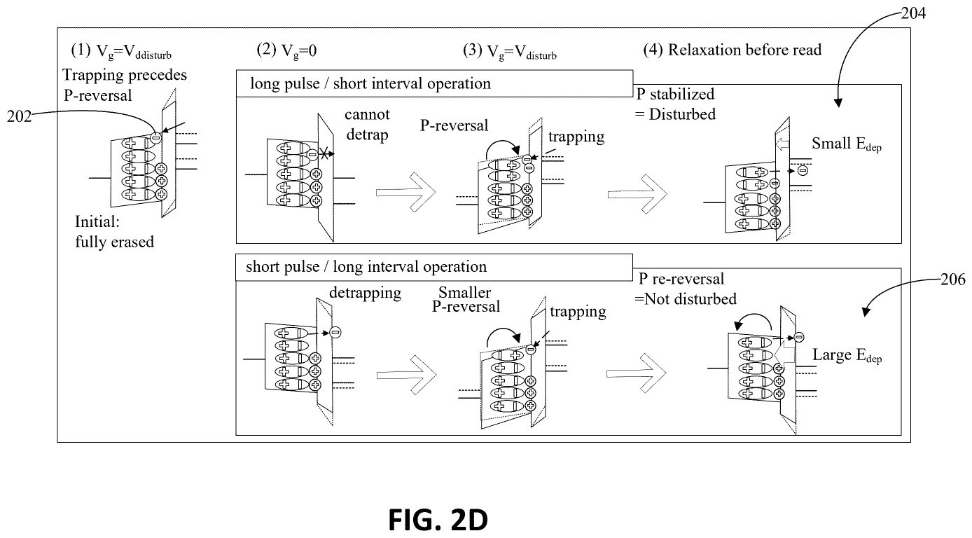

FIGS. 2A and 2B illustrate program disturb and read disturb in a ferroelectric memory cell. FIG. 2C illustrate trapped charges in a ferroelectric memory cell. As shown in FIG. 2A, during a program phase, a program voltage can be applied to a selected word line (e.g., WL0 in FIG. 1B). Unselected word lines (e.g., WL1, . . . , WLn in FIG. 1B) can be applied with a pass voltage that is smaller than the program voltage. However, a program disturb may occur, where the process of writing data to the selected memory cell (e.g., ferroelectric memory cell 104-1 in FIG. 1B) unintentionally affects the data stored in neighboring ferroelectric cells, potentially corrupting their stored information due to the electric field interactions within the ferroelectric material. For example, as illustrated in FIG. 2A, a target state for the selected memory cell can be “11.” Because of the program disturb, neighboring ferroelectric cells that have been programmed (e.g., to a “00” state or “01” state) may be unintentionally disturbed and changed to another state (e.g., state “10,” “11,” or a state between “11” and “10”). The disturb can occur because some of the electric dipoles in these cells flip their orientations.

As illustrated FIG. 2B, a read disturb can occur during a read phase. Similar to the program disturb, a read disturb in a ferroelectric memory cell can refer to a phenomenon where the act of reading data from one cell unintentionally alters the polarization state of neighboring cells, potentially corrupting the data stored within them. During a read phase, a read voltage Vread can be applied to a selected memory cell (e.g., ferroelectric memory cell 104-1 in FIG. 1B). Neighboring ferroelectric cells and/or the selected cells that have been programmed may flip the direction of their electric dipoles due to the electric field applied during the read phase, as illustrated in diagram (b) of FIG. 2B.

Frequent read and/or program operations can lead to cumulative fatigue of the ferroelectric material, increasing the risk of disturb. As illustrated in FIG. 2C, during the program or read phase, negative charges 207 can be trapped at an interface between a ferroelectric layer (e.g., the ferroelectric layer 152 of FIG. 1D) and a dielectric layer (e.g., the dielectric layer 156 of FIG. 1D). The ferroelectric layer 152 can have multiple electric dipoles 105 that are programmed to, e.g., a “11” state. The electric dipoles 105 can be coupled to the negative charges 207 and stabilized. However, during frequent read/program operations, more and more charges can be trapped at the interface. Charges 209 that are not coupled to the electric dipoles 105 can be unstable and create localized electric fields. These localized electric fields may interfere with the stable polarization states of the ferroelectric layer 152, causing unintended flip of dipole orientations and thereby leading to potential data errors. Therefore, both program disturb and read disturb can significantly reduce the reliability of a ferroelectric memory device.

In some implementations, an incremental step pulse programming (ISPP) is used to program the ferroelectric memory cells. A series of incrementally increasing voltage pulses can be applied to the selected word line (e.g., WL0 of FIG. 1B) during the ISPP programming process. As noted above, frequent pulses can lead to cumulative fatigue of the ferroelectric material (e.g., cumulative charges at the ferroelectric layer/dielectric layer interface), increasing the risk of data corruption. To reduce the program disturb and/or read disturb, the techniques described in the present disclosure can be used to de-trap the charges that have been accumulated at the interface between the ferroelectric layer 152 and the dielectric layer 156 (also called ferroelectric/dielectric interface in the present disclosure), thereby improving the reliability of a ferroelectric memory device.

FIG. 2D illustrates an example coupling model between polarization reversal and charge trapping during (1) an initial disturb pulse, (2) an interval, (3) a disturb pulse after the interval, and (4) relaxation before a read operation. It is understood that the example in FIG. 2D is for illustrating an example working principal for de-trapping charges and is not intended to be construed in a limiting sense. Other working principles for de-trapping charges are also possible and can be employed.

Two scenarios are shown in FIG. 2D: the scenario 204 is associated with a longer pulse time Tpulse of the disturb voltage and a shorter interval time Tinterval between successive pulses, while the scenario 206 is associated with a shorter pulse time Tpulse of the disturb pulse voltage and a longer interval time Tinterval between successive voltage pulses. The disturb pulse voltage can be a program voltage Vpgm, a read voltage Vread, or a pass voltage Vpass. In some examples, the disturb pulse voltage can be a program pulse voltage of a series of program pulse voltages during an ISPP.

As illustrated in FIG. 2D, for both scenarios 204 and 206, (1) first, due to the first disturb pulse, the charges 202 can be trapped at the interface between the ferroelectric layer 152 and the dielectric layer 156. For the scenario 204, (2) the trapped charges 202 may not be fully emitted or entrapped due to a short interval time Tinterval, and (3) are accumulated by the repeated disturb pulse. At reversed polarization (4), the accumulated charges may act to stabilize the reversed (disturbed) state by weakening the depolarization field (Edep).

By contrast, in the scenario 206, (2) the ferroelectric layer/dielectric layer interface can be kept discharged when the Tpulse is short, and the Tinterval is long enough for de-trapping charges 202 from the interface. In this scenario, an enhancement by the interfacial charges 202 may not occur. Thus, the polarization reversal rate can be lower. Even if some electric dipoles are reversed, the reversed electric dipoles can be unstable because the (4) insufficient coupled charge and large depolarization field can re-reverse the disturbed electric dipoles. Therefore, the unstabilization of the reversed electric dipoles can be a main factor for a disturb immunity.

To reduce the program or read disturb and enhance a disturb immunity, the implementation of the present disclosure employs a de-trapping field. Without limiting to any particular theory, the de-trapping field can unstabilize the reversed electric dipoles in the ferroelectric memory cells and/or reduce the trapped charges at the ferroelectric/dielectric interface of the ferroelectric memory cells. Unstable reversed electric dipoles can be reversed back to its original state, thereby lower data corruption rate and enhancing the reliability of a ferroelectric memory device.

FIG. 3A illustrates a schematic circuit diagram of an example ferroelectric memory array 300. FIG. 3B illustrates an example signal diagram of at least part of a program operation and a de-trapping operation. FIG. 3C illustrates another example signal diagram of at least part of a program operation and a de-trapping operation. FIG. 3D illustrates yet another example signal diagram of at least part of a program operation and a de-trapping operation. FIG. 3A is same as or substantially similar to FIG. 1B. For illustration purpose, the ferroelectric memory cells 104-1 will be used as an example selected memory cell in the subsequent discussions for simplicity. The selected ferroelectric memory cells 104-1 is coupled to the word line WL0 and the bit line BL0. Therefore, the BL0 can be referred to as a selected BL, and the word line WL0 can be referred to as selected WL in the subsequent discussions with reference to FIGS. 3A-3D. For ease of description, reference may be made to FIGS. 3A-3D when describing different implementations of signal diagrams during at least part of a program operation and a de-trapping operation.

As illustrated in FIGS. 3B-3D, at least part of the program operation can be performed during a program phase, and the de-trapping operation can be performed during a de-trapping phase. The program phase can correspond to the phase between time t0 and t1, while the de-trapping phase can refer to the phase between time t2 and t3. In some implementations, the de-trapping phase has a time duration equal to that of the program phase. In some implementations, the de-trapping phase has a time duration different from (e.g., longer than) the program phase. In some implementations, an intermediate phase exists between the program phase and the de-trapping phase, corresponding to the phase between time t1 and t2. In some implementations, a time duration of the intermediate phase is zero, e.g., no intermediate phase exists, and the de-trapping phase directly follows the program phase.

During a program phase, a program operation is performed on a selected ferroelectric memory cell 104-1. As illustrated in FIGS. 3B-3D, in some implementations, the program operation includes: applying a program voltage (e.g., Vpgm) to a selected word line WL0 coupled to the selected ferroelectric memory cell; and applying a pass voltage (e.g., Vpass) to an unselected word line (e.g., WL1, . . . , WLn) coupled to an unselected ferroelectric memory cell; applying a first BL voltage (e.g., Vss) to the selected bit line BL0; applying an inhibit voltage (e.g., Vinhib) to an unselected bit line (e.g., BL1, . . . , BLn); applying a first TSG voltage (e.g., Vconstant, or Vtsg of FIG. 1B) to an selected TSG (e.g., the TSG 108-T); applying a second TSG voltage (e.g., Vss) to an unselected TSG; applying a BSG voltage (e.g., Vss) to the BSG 106-T; and applying an ACS voltage (e.g., Vss) to a source line ACS. Vss can be a ground voltage (e.g., 0V). The first TSG voltage (e.g., Vconstant, or Vtsg of FIG. 1B) can be configured to turn on the selected TSG. Therefore, the channel of the selected ferroelectric memory cell 104-1 that is coupled to the selected bit line BL0 can be biased at a low voltage (e.g., Vss). The second TSG voltage (e.g., Vss) can be configured to turn off the unselected TSG. The second TSG voltage (e.g., Vss) can be smaller than the first TSG voltage (e.g., Vconstant, or Vtsg of FIG. 1B). It is to be understood that although during the program phase, BL0, unselected TSG, BSG and source line ACS are all applied with Vss in the example implementations shown in FIGS. 3B-3D, the voltages applied to each of these components can be different.

During the de-trapping phase, a de-trapping operation is performed. In some implementations, the de-trapping operation includes applying a first voltage to the unselected word line (e.g., WL1, . . . , WLn); applying a second voltage to a source line ACS; and applying a third voltage to a bit line (e.g., selected bit line BL0, and/or unselected bit line BL1, . . . , BLn). At least one of the second voltage or the third voltage is greater than the first voltage. Additionally, the de-trapping operation can include applying a WL voltage (e.g., Vss) to the selected word line WL0. As noted above, without limiting to any particular theory, the applied first to third voltages can unstabilize the reversed electric dipoles in the ferroelectric memory cells and/or reduce the trapped charges at the ferroelectric/dielectric interface of the ferroelectric memory cells. Unstable reversed electric dipoles can be reversed back to its original state, thereby lower data corruption rate and enhancing the reliability of a ferroelectric memory device. Three implementations of voltages applied to components of a memory array 300 during the de-trapping phase after the program phase are illustrated in FIGS. 3B-3D, respectively.

As illustrated in FIG. 3B, in some implementations, the first voltage applied to the unselected word line is negative, and an absolute value of the first voltage is smaller than an absolute value of the program voltage. In some implementations, the first voltage is smaller than zero. The second voltage applied to the source line ACS and the third voltage applied to the bit line are about zero (e.g., a value between −0.1V and 0.1V, between −0.05V and 0.05V, or between −0.01V and 0.01V). For example, the first voltage is a negative de-trapping voltage −V, the second voltage and the third voltage are Vss (e.g., 0V). An absolute value of the de-trapping voltage can be smaller than the absolute value of the program voltage, e.g., |−V|<|Vpgm|. In the example implementation illustrated in FIG. 3B, the TSGs and the BSG can be configured to be turned off during the de-trapping phase, e.g., by applying a ground voltage Vss.

As illustrated in FIG. 3C, in some implementations, the second voltage applied to the source line ACS is positive, and the second voltage is smaller than a first erase voltage that is applied to the source line ACS during an erase phase. In some implementations, the first voltage applied to the unselected word line is about zero (e.g., a value between −0.1V and 0.1V, between −0.05V and 0.05V, or between −0.01V and 0.01V), the second voltage is greater than zero, and the third voltage applied to the bit line is about zero (e.g., a value between −0.1V and 0.1V, between −0.05V and 0.05V, or between −0.01V and 0.01V). For example, as illustrated in FIG. 3C, the first voltage is Vss (e.g., 0V), the second voltage is a first de-trapping voltage V1, and the third voltage is Vss (e.g., 0V). The de-trapping voltage V1 can be smaller than an erase voltage during the erase phase to avoid unintentional erasure of data stored in the programmed memory cells. For example, the erase voltage can range between 5V and 10V. In some implementations, the selected TSG and unselected TSGs are applied with an off voltage (e.g., Vss) at the de-trapping phase. Therefore, the selected TSG and unselected TSGs can be turned off during the de-trapping phase in the example implementation shown in FIG. 3C.

With continued reference to FIG. 3C, in some implementations, the de-trapping operation includes applying a fourth voltage (e.g., Vss) to a BSG; and after a first predetermined period, floating the BSG. The first predetermined period can be shorter than a ramping period of the second voltage. For example, the ramping period of the second voltage can refer to a time duration between time t2 (e.g., when the second voltage starts to ramp) and time t4 (e.g., when the second voltage is fully or substantially ramped to a target value V1). The fourth voltage can be Vss. The BSG can be configured to be applied with Vss when the de-trapping phase starts at time t2. After a predetermined period, at time t5 (e.g., between time t2 and time t4), the BSG can be configured to be floated (e.g., with no voltage applied to it). The dashed line for the BSG voltage indicates a floating voltage Vfloat. Without limiting to any particular theory, by floating the BSG, gate-induced drain leakage (GIDL) can be used here to assist the transfer of the ACS voltage to the channels of ferroelectric memory cells.

As illustrated in FIG. 3D, in some implementations, the third voltage that is applied to the bit line is positive, and the third voltage is smaller than a second erase voltage that is applied to the bit line during an erase phase. In some implementations, the first voltage and the second voltage are about zero (e.g., a value between −0.1V and 0.1V, between −0.05V and 0.05V, or between −0.01V and 0.01V), and the third voltage is greater than zero. For example, as illustrated in FIG. 3D, the first voltage is Vss (e.g., 0V), the second voltage is Vss (e.g., 0V), and the third voltage is a second de-trapping voltage V2. The second de-trapping voltage V2 can be the same or different from the first de-trapping voltage V1. Similar to the first de-trapping voltage V1, the second de-trapping voltage V2 can be smaller than an erase voltage during the erase phase to avoid unintentional erasure of data stored in the programmed memory cells. In some implementations, the BSG is applied with an off voltage (e.g., Vss) during the de-trapping phase.

With continued reference to FIG. 3D, in some implementations, the de-trapping operation includes applying a fifth voltage (e.g., Vss) to a TSG (e.g., selected and/or unselected TSGs); and after a second predetermined period, floating the TSG. The second predetermined period can be shorter than a ramping period of the third voltage. For example, the ramping period of the third voltage can refer to a time duration between time t2 (e.g., when the third voltage starts to ramp) and time t6 (e.g., when the third voltage is fully or substantially ramped to a target value V2). The fifth voltage can be Vss. The TSG can be configured to be applied with Vss when the de-trapping phase starts at time t2. After a predetermined period, at time t7 (e.g., between time t2 and time t6), the TSG can be configured to be floated. The dashed line for the TSG voltage indicates a floating voltage Vfloat. Without limiting to any particular theory, gate-induced drain leakage (GIDL) can be used here to assist the transfer of the BL voltage to the channels of ferroelectric memory cells. In some implementations, although not shown in FIG. 3D, the unselected TSG can be configured to applied with an off voltage (e.g., Vss) during the entire de-trapping phase (e.g., time period between t2 and t3) without floating.

In some implementations, as noted above, an ISPP operation is employed to program a ferroelectric memory cell. Instead of applying a single high voltage pulse to program a cell, ISPP uses a sequence of pulses with progressively increasing program voltage levels, e.g., each pulse step applies a slightly higher voltage than the previous one. The sequence of pulses can be correspondingly applied during the plurality of periods. In some implementations, the de-trapping operation is performed after the last period of the plurality of periods in the ISPP. The last period of the plurality of periods in the ISPP corresponds to a final programming step or pulse in the series of incremental voltage pulses.

Alternatively, the de-trapping operation can be performed after each period of the plurality of periods during an ISPP process, e.g., between successive program voltage pulses. This can ensure that charge accumulation can be continuously managed through the ISPP process, further reducing the likelihood of charge buildup that may lead to programming errors.

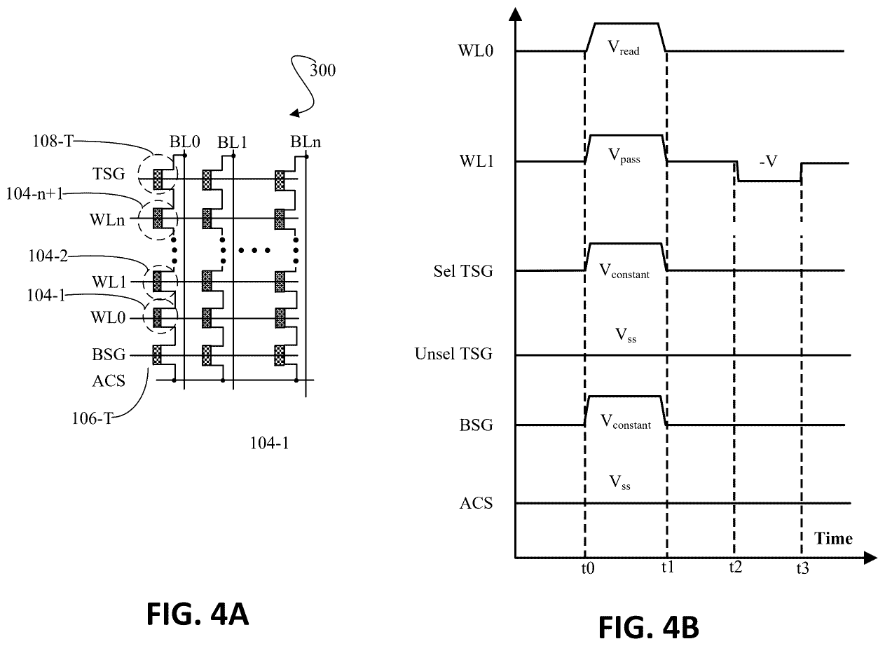

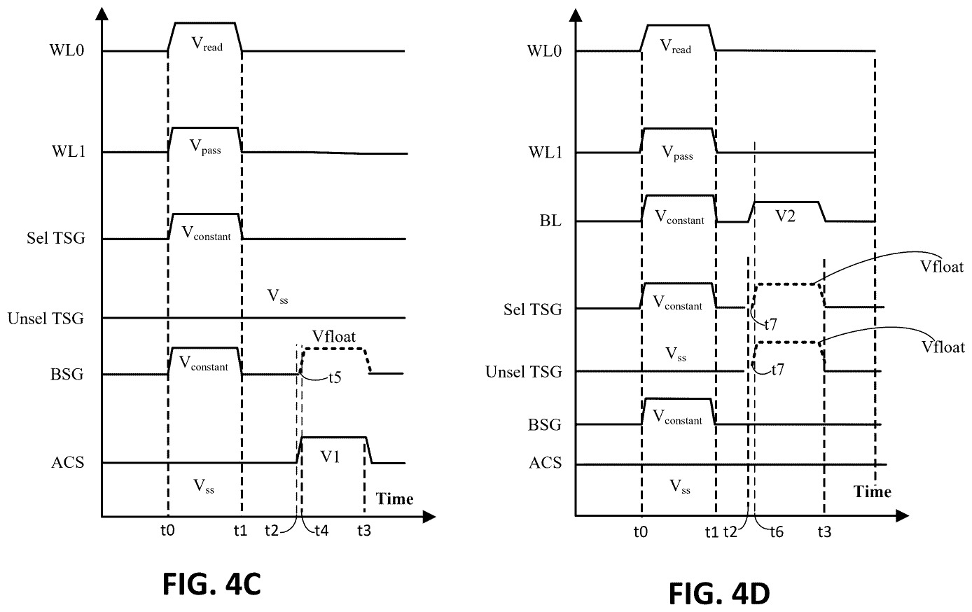

FIG. 4A illustrates a schematic circuit diagram of the example ferroelectric memory array 300 of FIG. 3A. FIG. 4A is identical to FIG. 3A. FIG. 4B illustrates an example signal diagram of a read operation and a de-trapping operation. FIG. 4C illustrates another example signal diagram of a read operation and a de-trapping operation. FIG. 4D illustrates yet another example signal diagram of a read operation and a de-trapping operation. For illustration purpose, the ferroelectric memory cells 104-1 will be used as an example selected memory cell in the subsequent discussions for simplicity. The selected ferroelectric memory cells 104-1 is coupled to the word line WL0 and the bit line BL0, as illustrated in FIG. 4A. Therefore, the BL0 can be referred to as a selected BL, and the word line WL0 can be referred to as selected WL in the subsequent discussions with reference to FIGS. 4A-4D. For ease of description, reference may be made to FIGS. 4A-4D when describing different embodiments of signal diagrams during a read operation and a de-trapping operation.

As illustrated in FIGS. 4B-4D, a read phase can correspond to the phase between time t0 and t1, while a de-trapping phase can refer to the phase between time t2 and t3. In some implementations, the de-trapping phase has a time duration equal to that of the read phase. In some implementations, the de-trapping phase has a time duration different from (e.g., longer than) the read phase. In some implementations, an intermediate phase exists between the read phase and the de-trapping phase, corresponding to the phase between time t1 and t2. In some implementations, a time duration of the intermediate phase is zero, e.g., no intermediate phase exists, and the de-trapping phase directly follows the read phase.

During a read phase, a read operation is performed on a selected ferroelectric memory cell 104-1. As illustrated in FIGS. 4B-4D, in some implementations, the read operation includes: applying a read voltage (e.g., Vread) to a selected word line WL0 coupled to the selected ferroelectric memory cell 104-1; and applying a pass voltage (e.g., Vpass) to a unselected word line (e.g., WL1, . . . , WLn) coupled to an unselected ferroelectric memory cell (e.g., WL1 coupled to unselected ferroelectric memory cell 104-2); applying a BL voltage (e.g., Vconstant) to a bit line (e.g., BL0, . . . , BLn); applying a first TSG voltage (e.g., Vconstant) to an selected TSG (e.g., the TSG 108-T); applying a second TSG voltage (e.g., Vss) to an unselected TSG; applying a BSG voltage (e.g., Vconstant) to the BSG 106-T; and applying an ACS voltage (e.g., Vss) to a source line ACS. Vss can be a ground voltage. The first TSG voltage (e.g., Vconstant) can be configured to turn on the selected TSG. The second TSG voltage (e.g., Vss) can be configured to turn off the unselected TSG. The BSG voltage (e.g., Vconstant) can be configured to turn on the BSG. The second TSG voltage can be smaller than the first TSG voltage. It is to be understood that although during the read phase, unselected TSG and source line ACS are all applied with Vss in the example implementations shown in FIGS. 4B-4D, the voltages applied to each of these components can be different. Additional details on the effect or function of each voltage duirng the read operation have been described above in reference to FIG. 1B.

During the de-trapping phase, a de-trapping operation is performed. The de-trapping operation following a read operation can be the same as or substantially similar to the de-trapping operation following a program operation (e.g., as described above in reference to FIGS. 3A-3D). In some implementations, the de-trapping operation includes applying a first voltage to the unselected word line (e.g., WL1, . . . , WLn); applying a second voltage to a source line ACS; and applying a third voltage to a bit line (e.g., selected bit line BL0, and/or unselected bit line BL1, . . . , BLn). At least one of the second voltage or the third voltage is greater than the first voltage. Additionally, the de-trapping operation can include applying a WL voltage (e.g., Vss) to the selected word line WL0. As noted above, without limiting to any particular theory, the applied first to third voltages can unstabilize the reversed electric dipoles in the ferroelectric memory cells and/or reduce the trapped charges at the ferroelectric/dielectric interface of the ferroelectric memory cells. Unstable reversed electric dipoles can be reversed back to its original state, thereby lower data corruption rate and enhancing the reliability of a ferroelectric memory device. Three implementations of voltages applied to components of a memory array during a de-trapping phase after a read phase are illustrated in FIGS. 4B-4D, respectively.

As illustrated in FIG. 4B, in some implementations, the first voltage is negative, and an absolute value of the first voltage is smaller than an absolute value of the program voltage. In some implementations, the first voltage is smaller than zero, and the second voltage and the third voltage are about zero (e.g., a value between −0.1V and 0.1V, between −0.05V and 0.05V, or between −0.01V and 0.01V). For example, the first voltage is a negative de-trapping voltage −V, the second voltage and the third voltage are Vss (e.g., 0V). An absolute value of the de-trapping voltage can be smaller than the absolute value of the program voltage, e.g., |−V|<|Vpgm|. In the example implementation illustrated in FIG. 4B, the TSGs and the BSG can be configured to be turned off during the de-trapping phase, e.g., by applying an off voltage Vss.

As illustrated in FIG. 4C, in some implementations, the second voltage is positive, and the second voltage is smaller than a first erase voltage that is applied to the source line ACS during an erase phase. In some implementations, the first voltage is about zero (e.g., a value between −0.1V and 0.1V, between −0.05V and 0.05V, or between −0.01V and 0.01V), the second voltage is greater than zero, and the third voltage is about zero (e.g., a value between −0.1V and 0.1V, between −0.05V and 0.05V, or between −0.01V and 0.01V). For example, as illustrated in FIG. 4C, the first voltage applied to the WL0 is Vss (e.g., 0V), the second voltage applied to the ACS is a first de-trapping voltage V1, and the third voltage applied to the BL is Vss (not shown). The de-trapping voltage V1 can be smaller than an erase voltage during the erase phase to avoid unintentional erasure of data stored in the programmed memory cells. For example, the erase voltage can range between 5V and 10V. In the example implementation illustrated in FIG. 4C, the selected TSGs and the unselected TSG can be configured to be turned off during the de-trapping phase, e.g., by applying an off voltage Vss. It is to be noted that the first de-trapping voltage V1 in the example implementation shown in FIG. 4C can be different from or same as the first de-trapping voltage V1 in the example implementation shown in FIG. 3C.

With continued reference to FIG. 4C, in some implementations, the de-trapping operation includes applying a fourth voltage to a BSG; and after a first predetermined period, floating the BSG. The first predetermined period can be shorter than a ramping period of the second voltage. For example, the ramping period of the second voltage can refer to a time duration between time t2 (e.g., when the second voltage starts to ramp) and time t4 (e.g., when the second voltage is fully or substantially ramped to a target value V1). The fourth voltage can be Vss. The BSG can be configured to be applied with Vss when the de-trapping phase starts at time t2. After a predetermined period, at time t5 (e.g., between time t2 and time t4), the BSG can be configured to be floated. The dashed line for the BSG voltage in FIG. 4C indicates a floating voltage Vfloat. Without limiting to any particular theory, GIDL can be used here to assist the transfer of the ACS voltage. It is to be noted that a duration of the first determined period in the example implementation shown in FIG. 4C can be different from or same as a duration of the first determined period in the example implementation shown in FIG. 3C.

As illustrated in FIG. 4D, in some implementations, the third voltage is positive, and the third voltage is smaller than a second erase voltage that is applied to the bit line during an erase phase. In some implementations, the first voltage and the second voltage are about zero (e.g., a value between −0.1V and 0.1V, between −0.05V and 0.05V, or between −0.01V and 0.01V), and the third voltage is greater than zero. For example, as illustrated in FIG. 4D, the first voltage applied to the selected word line WL0 is Vss (e.g., 0V), the second voltage applied to the source line ACS is Vss (e.g., 0V), and the third voltage applied to the bit line (e.g., selected and/or unselected BLs) is a second de-trapping voltage V2. The second de-trapping voltage V2 can be the same or different from the first de-trapping voltage V1 that is applied to the source line ACS in the example implementation shown in FIG. 4C. Similar to the first de-trapping voltage V1, the second de-trapping voltage V2 can be smaller than an erase voltage during the erase phase to avoid unintentional erasure of data stored in the programmed memory cells. In some implementations, the BSG is configured to be turned off during the de-trapping phase, e.g., by applying Vss. It is to be noted that the second de-trapping voltage V2 in the example implementation shown in FIG. 4D can be different from or same as the second de-trapping voltage V2 in the example implementation shown in FIG. 3D.

With continued reference to FIG. 4D, in some implementations, the de-trapping operation includes applying a fifth voltage to a TSG (e.g., selected and/or unselected TSGs); and after a second predetermined period, floating the TSG. The second predetermined period can be shorter than a ramping period of the third voltage. For example, the ramping period of the third voltage can refer to a time duration between time t2 (e.g., when the third voltage starts to ramp) and time t6 (e.g., when the third voltage is fully or substantially ramped to a target value V2). The fifth voltage can be Vss. The TSG can be configured to be applied with Vss when the de-trapping phase starts at time t2. After a second predetermined period, at time t7 (e.g., between time t2 and time t6), the TSG can be configured to be floated. The dashed line for the TSG voltage indicates a floating voltage V_{float}. Without limiting to any particular theory, GIDL can be used here to assist the transfer of the BL voltage. In some implementations, although not shown in FIG. 4D, the unselected TSG can be configured to applied with an off voltage (e.g., Vss) during the entire de-trapping phase (e.g., time period between t2 and t3) without floating. In other words, the unselected TSG can be configured to be turned off during the entire de-trapping phase. It is to be noted that a duration of the second determined period in the example implementation shown in FIG. 4D can be different from or same as a duration of the second determined period in the example implementation shown in FIG. 3D.

In some implementations, a plurality of read operations are correspondingly performed on a plurality of ferroelectric memory cells, and the de-trapping operation is performed after performing the plurality of read operations. For example, as illustrated in FIG. 4A, a plurality of read operations can be performed on n+1 ferroelectric memory cells (e.g., 104-1, 104-2, . . . , 104-(n+1)), respectively. After reading these ferroelectric memory cells, a de-trapping operation can be performed. In some examples, a de-trapping operation can be performed after all ferroelectric memory cells in a memory block have been read.

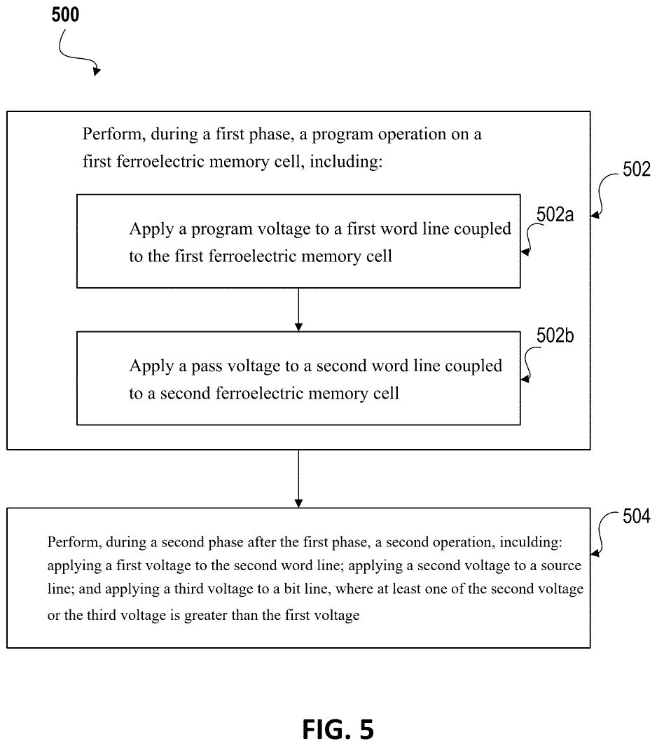

FIG. 5 is a flow chart of a process 500 of an example method to operate a ferroelectric memory device. The ferroelectric memory device can be, e.g., the ferroelectric memory device 100 of FIG. 1C.

At step 502, during a first phase, a program operation is performed on a first ferroelectric memory cell. The program operation includes applying (e.g., step 502a) a program voltage to a first word line coupled to the first ferroelectric memory cell, and applying (e.g., step 502b) a pass voltage to a second word line coupled to a second ferroelectric memory cell. The first phase can be, e.g., the program phase between time t0 and t1 in FIGS. 3B-3D. The first ferroelectric memory cell can be, e.g., the selected ferroelectric memory cell 104-1 of FIGS. 1B and 3A. The first word line can be, e.g., the selected word line WL0 of FIGS. 1B and 3A-3D. The program voltage can be, e.g., the program voltage Vpgm of FIGS. 3B-3D. The pass voltage can be, e.g., the pass voltage Vpass of FIGS. 3B-3D. The second word line can be, e.g., any one of unselected word lines WL1, . . . , WLn of FIGS. 1B and 3A, or WL1 of FIGS. 3B-3D. The second ferroelectric memory cell can be, e.g., the unselected ferroelectric memory cell 104-2 of FIG. 3A.

At step 504, during a second phase after the first phase, a second operation is performed. The second operation includes: applying a first voltage to the second word line; applying a second voltage to a source line; and applying a third voltage to a bit line, where at least one of the second voltage or the third voltage is greater than the first voltage. The second phase can be, e.g., the de-trapping phase between t2 and t3 in FIGS. 3B-3D. The second operation can be, e.g., the de-trapping operation described above in reference to FIGS. 3B-3D. The first voltage can be, e.g., the negative de-trapping voltage-V of FIG. 3B, or the first voltage (e.g., Vss) of FIGS. 3C and 3D. The second voltage can be, e.g., the second voltage (e.g., Vss) of FIGS. 3B and 3D, or the first de-trapping voltage V1 of FIG. 3C. The third voltage can be, e.g., the third voltage (e.g., Vss) of FIGS. 3B and 3C, or the second de-trapping voltage V2 of FIG. 3D. The source line can be, e.g., the source line ACS of FIGS. 1B and 3A. The bit line can be, e.g., the selected bit line BL0 of FIGS. 1B and 3A-3D, or any one of unselected bit lines BL1, . . . , BLn of FIGS. 1B and 3A, or BL1 of FIGS. 3B-3D.

In some implementations, the first voltage is smaller than zero, and the second voltage and the third voltage are about zero. A voltage about zero can refer to a voltage value between −0.1V and 0.1V, between −0.05V and 0.05V, or between −0.01V and 0.01V.

In some implementations, the first voltage is about zero, the second voltage is greater than zero, and the third voltage is about zero, and where performing, during the second phase after the first phase, the second operation further includes: applying a fourth voltage to a bottom select gate (BSG); and after a first predetermined period, floating the BSG, as described in reference to FIG. 3C. The BSG can be, e.g., the BSG of FIGS. 1B and 3A-3D. The fourth voltage can be, e.g., Vss. The first predetermined period can be, e.g., the period between t2 and t5 in FIG. 3C.

In some implementations, the first predetermined period is shorter than a ramping time for the second voltage. The ramping time for the second voltage can be, e.g., the period between t2 and t4 in FIG. 3C.

In some implementations, the first voltage and the second voltage are about zero, and the third voltage is greater than zero, and where performing, during the second phase after the first phase, the second operation further includes: applying a fifth voltage to a top select gate (TSG); and after a second predetermined period, floating the TSG, as described in reference to FIG. 3D. The TSG can be, e.g., a selected TSG 108 of FIGS. 1B and 3A, a selected TSG of FIGS. 3B-3D, or an unselected TSG of FIGS. 3B-3D. The fifth voltage can be, e.g., Vss. The second predetermined period can be, e.g., the period between t2 and t7 in FIG. 3D.

In some implementations, the second predetermined period is shorter than a ramping time for the third voltage. The ramping time for the third voltage can be, e.g., the period between t2 and t6 in FIG. 3D.

In some implementations, the bit line is a first bit line coupled to the first ferroelectric memory cell, and where performing, during the first phase, the program operation on the first ferroelectric memory cell further includes: applying a first bit line voltage to the first bit line; applying a second bit line voltage greater than the first bit line voltage to a second bit line; and applying a source line voltage to the source line. The first bit line can be, e.g., the selected bit line BL0 of FIGS. 1B and 3A-3D. The second bit line can be, e.g., any one of unselected bit lines BL1, . . . , BLn of FIGS. 1B and 3A, or the unselected bit line BL1 of FIGS. 3B-3D. The first bit line voltage can be, e.g., Vss. The second bit line voltage can be, e.g., an inhibit voltage Vinhib of FIGS. 3B-3D. The source line voltage can be, e.g., Vss.

In some implementations, the first voltage is negative, and an absolute value of the first voltage is smaller than an absolute value of the program voltage.

In some implementations, the second voltage is positive, and the second voltage is smaller than a first erase voltage that is applied to the source line during an erase phase, as described above in reference to FIG. 3C.

In some implementations, the third voltage is positive, and the third voltage is smaller than a second erase voltage that is applied to the bit line during an erase phase, as described above in reference to FIG. 3D.

In some implementations, performing, during the first phase, the program operation on the first ferroelectric memory cell further includes: applying, during the first phase, a BSG voltage to a BSG; applying, during the first phase, a first TSG voltage to a selected TSG; and applying, during the first phase, a second TSG voltage smaller than the first TSG voltage to an unselected TSG. The BSG voltage can be, e.g., Vss. The first TSG voltage can be, e.g., Vconstant of FIGS. 3B-3D, or Vtsg of FIG. 1B. The second TSG voltage can be, e.g., Vss.

In some implementations, the method includes performing an increment step pulse programming (ISPP) operation to cause the first ferroelectric memory cell to be a programmed state. Performing the ISPP operation includes applying a plurality of program voltages during a plurality of periods. A last period of the plurality of periods includes the first phase, and a last one of the plurality of program voltages includes the program voltage. Performing the second operation includes performing the second operation during the second phase after the last period of the plurality of periods, as described above in reference to FIGS. 3A-3D.

In some implementations, the method includes performing an increment step pulse programming (ISPP) operation to cause the first ferroelectric memory cell to a programmed state. Performing the ISPP operation includes applying a plurality of program voltages during a plurality of periods. Each of the plurality of periods includes the first phase, the plurality of program voltages includes the program voltage, and the plurality of program voltages is different from one another. Performing the second operation includes performing the second operation during the second phase after each period of the plurality of periods, as described above in reference to FIGS. 3A-3D.

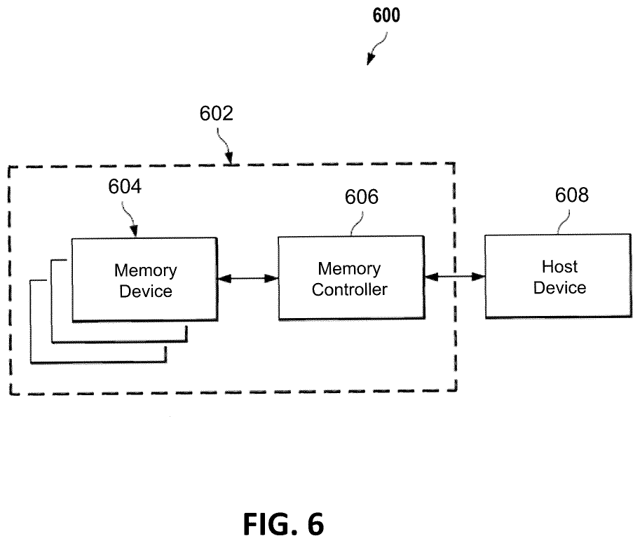

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D ferroelectric memory device 100 of FIG. 1C, or a part of the 3D semiconductor device 100 (e.g., the capacitor structure 150 of FIG. 1D, or the ferroelectric memory array 160 of FIG. 1B, or the ferroelectric memory array 300 of FIGS. 3A and 4A).

In some implementations, a 3D memory device 604 includes a ferroelectric memory device, or a FE-NAND device. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one implementation,” “an implementation,” “an example implementation,” “some implementations,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (e.g., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances.

The terms “approximately,” and “about,” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. e.g., .+−.10%, .+−.20%, or .+−.30% of the value), but is not limited thereto.

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method of operating a ferroelectric memory device, comprising:
performing, during a first phase, a program operation on a first ferroelectric memory cell, comprising:
applying a program voltage to a first word line coupled to the first ferroelectric memory cell, and
applying a pass voltage to a second word line coupled to a second ferroelectric memory cell; and
performing, during a second phase after the first phase, a second operation, comprising:
applying a first voltage to the second word line;
applying a second voltage to a source line; and
applying a third voltage to a bit line,
wherein at least one of the second voltage or the third voltage is greater than the first voltage.

2. The method of claim 1, wherein the first voltage is smaller than zero, and the second voltage and the third voltage are about zero.

3. The method of claim 1, wherein the first voltage is about zero, the second voltage is greater than zero, and the third voltage is about zero, and wherein performing, during the second phase after the first phase, the second operation further comprises:
applying a fourth voltage to a bottom select gate (BSG); and
after a first predetermined period, floating the BSG.

4. The method of claim 1, wherein the first voltage and the second voltage are about zero, and the third voltage is greater than zero, and wherein performing, during the second phase after the first phase, the second operation further comprises:
applying a fifth voltage to a top select gate (TSG); and
after a second predetermined period, floating the TSG.

5. The method of claim 1, wherein the bit line is a first bit line coupled to the first ferroelectric memory cell, and wherein performing, during the first phase, the program operation on the first ferroelectric memory cell further comprises:
applying a first bit line voltage to the first bit line;
applying a second bit line voltage greater than the first bit line voltage to a second bit line; and
applying a source line voltage to the source line.

6. The method of claim 1, wherein the first voltage is negative, and an absolute value of the first voltage is smaller than an absolute value of the program voltage.

7. The method of claim 1, wherein the second voltage is positive, and the second voltage is smaller than a first erase voltage that is applied to the source line during an erase phase.

8. The method of claim 1, wherein the third voltage is positive, and the third voltage is smaller than a second erase voltage that is applied to the bit line during an erase phase.

9. The method of claim 1, comprising:
performing an increment step pulse programming (ISPP) operation to cause the first ferroelectric memory cell to be a programmed state, wherein performing the ISPP operation comprises applying a plurality of program voltages during a plurality of periods,
wherein a last period of the plurality of periods comprises the first phase, and a last one of the plurality of program voltages comprises the program voltage, and
wherein performing the second operation comprises performing the second operation during the second phase after the last period of the plurality of periods.

10. The method of claim 1, comprising:
performing an increment step pulse programming (ISPP) operation to cause the first ferroelectric memory cell to a programmed state, wherein performing the ISPP operation comprises applying a plurality of program voltages during a plurality of periods,
wherein each of the plurality of periods comprises the first phase, the plurality of program voltages comprises the program voltage, and the plurality of program voltages is different from one another, and
wherein performing the second operation comprises performing the second operation during the second phase after each period of the plurality of periods.

11. A method of operating a ferroelectric memory device, comprising:
performing, during a first phase, a read operation on a first ferroelectric memory cell, comprising:
applying a read voltage to a first word line coupled to the first ferroelectric memory cell, and
applying a pass voltage to a second word line coupled to a second ferroelectric memory cell; and
performing, during a second phase after the first phase, a second operation, comprising:
applying a first voltage to the second word line;
applying a second voltage to a source line; and
applying a third voltage to a bit line,
wherein at least one of the second voltage or the third voltage is greater than the first voltage.

12. The method of claim 11, wherein the first voltage is smaller than zero, and the second voltage and the third voltage are about zero.

13. The method of claim 11, wherein the first voltage is about zero, the second voltage is greater than zero, and the third voltage is about zero, and wherein performing, during the second phase after the first phase, the second operation further comprises:
applying a fourth voltage to a bottom select gate (BSG); and
after a first predetermined period, floating the BSG.

14. The method of claim 11, wherein the first voltage and the second voltage are about zero, and the third voltage is greater than zero, and wherein performing, during the second phase after the first phase, the second operation further comprises:
applying a fifth voltage to a top select gate (TSG); and
after a second predetermined period, floating the TSG.

15. The method of claim 11, wherein performing, during the first phase, the read operation on the first ferroelectric memory cell further comprises:
applying a source line voltage to the source line; and
applying a bit line voltage to the bit line.

16. The method of claim 11, wherein the first voltage is negative, and an absolute value of the first voltage is smaller than an absolute value of a program voltage.

17. The method of claim 11, wherein the second voltage is positive, and the second voltage is smaller than a first erase voltage that is applied to the source line during an erase phase.

18. The method of claim 11, wherein the third voltage is positive, and the third voltage is smaller than a second erase voltage that is applied to the bit line during an erase phase.

19. The method of claim 11, comprising:
performing, during a plurality of phases, a plurality of read operations on a plurality of ferroelectric memory cells, wherein the plurality of phases comprises the first phase, the plurality of read operations comprises the read operation, and the plurality of ferroelectric memory cells comprises the first ferroelectric memory cell, and
wherein the second operation is performed after performing the plurality of read operations on the plurality of ferroelectric memory cells.

20. A ferroelectric memory device, comprising:
a memory array comprising a first word line and a second word line; and
a peripheral circuit coupled to the memory array, wherein the peripheral circuit is configured to perform operations comprising:
performing, during a first phase, a program operation on a first ferroelectric memory cell, comprising:
applying a program voltage to the first word line coupled to the first ferroelectric memory cell, and
applying a pass voltage to the second word line coupled to a second ferroelectric memory cell; and
performing, during a second phase after the first phase, a second operation, comprising:
applying a first voltage to the second word line;
applying a second voltage to a source line; and
applying a third voltage to a bit line,
wherein at least one of the second voltage or the third voltage is greater than the first voltage.
